(19) United States
(12) Patent Application Publication
(10) Pub. No.: US 2024/0186227 A1
(43) Pub. Date: Jun. 6, 2024

(54) INTEGRATED CIRCUIT PACKAGE ARCHITECTURES WITH CORE AND/OR BUILD-UP LAYERS COMPRISING SPIN-ON GLASS (SOG)

(71) Applicant: Intel Corporation, Santa Clara, CA (US)

(72) Inventors: Haobo Chen, Chandler, AZ (US); Bohan Shan, Chandler, AZ (US); Kyle J. Arrington, Gilbert, AZ (US); Kristof Darmawikarta, Chandler, AZ (US); Gang Duan, Chandler, AZ (US); Jeremy D. Ecton, Gilbert, AZ (US); Hongxia Feng, Chandler, AZ (US); Xiaoying Guo, Chandler, AZ (US); Ziyin Lin, Chandler, AZ (US); Brandon Christian Marin, Gilbert, AZ (US); Srinivas V. Pietambaram, Chandler, AZ (US); Dingying Xu, Chandler, AZ (US)

(73) Assignee: Intel Corporation, Santa Clara, CA (US)

(21) Appl. No.: 18/061,181

(22) Filed: Dec. 2, 2022

(51) Int. Cl. H01L 23/498; H01L 21/48; H01L 23/00; H01L 23/538; H01L 23/64; H01L 25/065; H05K 1/02; H05K 1/03; H05K 1/11; H05K 1/18; H05K 3/46

(52) U.S. Cl. CPC H01L 23/49822; H01L 21/4857; H01L 21/486; H01L 23/49816; H01L 23/49838; H01L 23/5381; H01L 23/5383; H01L 23/5386; H01L 23/642; H01L 24/16; H01L 24/32; H01L 24/73; H01L 25/0655; H05K 1/0271; H05K 1/0306; H05K 1/113; H05K 1/181; H05K 3/4605; H01L 2224/16235; H01L 2224/32225; H01L 2224/73204; H01L 2924/15174; H01L 2924/157; H01L 2924/15788; H05K 2201/0195

(57) ABSTRACT

In one embodiment, an integrated circuit package substrate includes a core layer comprising a plurality of metal vias electrically coupling a first side of the core layer and a second side of the core layer opposite the first side. The package substrate further includes a build-up layer on the first side of the core layer, the build-up layer comprising metal vias within a dielectric material and electrically connected to the metal vias of the core layer. The dielectric material includes Silicon, Oxygen, and at least one of Boron or Phosphorus.

### BACKGROUND

Continued growth in computing and mobile devices will continue to increase the demand for greater bandwidth density within and reliability of semiconductor packages. Package substrates may include a glass core for better package stability/warping sensitivity. However, glass cores may present other issues caused by mismatches between the glass and metal vias inside or on the core, and/or between the glass and organic materials used for build-up layers on the core.

### BRIEF DESCRIPTION OF THE DRAWINGS

FIG. 1 illustrates an example cross-section of a package substrate that includes a core and build-up (BU) layers formed from a spin-on-glass (SOG) material in accordance with embodiments of the present disclosure.

FIGS. 2A-2B illustrate example processes for manufacturing a package substrate core that is formed using a SOG material in accordance with embodiments of the present disclosure.

FIGS. 3A-3E illustrate an example process for manufacturing build-up (BU) layers of a package substrate in accordance with embodiments of the present disclosure.

FIGS. 4A-4C illustrate another example process for manufacturing build-up (BU) layers of a package substrate in accordance with embodiments of the present disclosure.

FIG. 5 illustrates an example package substrate that may incorporate one or more aspects of the present disclosure.

FIG. 6 illustrates an example multi-die package that may incorporate one or more aspects of the present disclosure.

FIGS. 7A-7B illustrate example systems that may incorporate the glass core architectures described herein.

FIG. 8 is a top view of a wafer and dies that may be included in a microelectronic assembly, in accordance with any of the embodiments disclosed herein.

FIG. 9 is a cross-sectional side view of an integrated circuit device that may be included in a microelectronic assembly, in accordance with any of the embodiments disclosed herein.

FIG. 10 is a block diagram of an example electrical device that may include a microelectronic assembly, in accordance with any of the embodiments disclosed herein.

### DETAILED DESCRIPTION

Integrated circuit devices continue to shrink in size, and with this shrinkage, improving device performance has been focused on achieving chip stacking using thinned chips, and increasing input/output (I/O) density in the substrate for multichip integration. Manufacturing these ever-shrinking apparatuses has been made possible with a rigid carrier, such as a glass carrier, in a temporary bonding and debonding technology. However, one of the challenges associated with the temporary bonding and debonding technology is the warpage or shrinkage control after removal of the rigid carrier. Once the rigid glass carrier is de-bonded, the substrate might warp due to inbuilt residual stress and CTE (coefficient of thermal efficiency) mismatches between various components, e.g., between Silicon (˜2.6 ppm/° C.), ABF (Ajinomoto Build-up Film, ˜39 ppm/° C.) in the build-up (BU) layers, and Copper (˜17 ppm/° C.) vias/traces. This can impact certain back-end processes (e.g., bump formation) as well as the assembly process.

One way to address the above problem is to use glass as a permanent substrate core, as the glass core can restrict warpage and scaling and thereby may maintain a total thickness variation (TTV) of approximately 2-3 μm for ≤30 μm bump pitch scaling. However, there may be a mismatch in CTE between a glass core and metal (e.g., Copper) used to fill in the through-glass vias (TGVs) in the core or to create traces on a surface of the core, and/or certain materials used for build-up (BU) layers above and/or below the core (e.g., organic materials, such as ABF). For instance, Copper may have a CTE of approximately 16-17 ppm/° C. compared to the CTE of glass, which might be between approximately 3-8 ppm/° C. This CTE mismatch can cause the glass core to be more brittle. For example, as the core is heated (e.g., during a processing step), the glass core can crack due to the Copper expanding at a higher rate, and at cold temperatures, there may be a risk of Copper delamination as it shrinks at a higher rate. As used herein, “glass” (as opposed to “spin-on-glass”) may refer to an SiOx analog material with or without modifier ions. An example glass material may be silica (SiO2).

In embodiments herein, integrated circuit devices may include package substrates that implement a permanent core that is made from a spin-on-glass (SOG) material and/or implement a SOG material in one or more of the build-up (BU) layers as a dielectric. Processes for forming such package substrates and devices are also disclosed herein. As used herein, spin-on-glass (SOG) or a SOG material may refer to a material that begins in a liquid form having R-groups within a Silicon-Oxygen backbone dissolved in a solvent, e.g., an alcohol. In some embodiments, the SOG material may include an inorganic silicate, organic siloxane, or silanol based material. The material may go through a thermal annealing process that causes Si—O—Si bonding to form within the material. Aspects of the annealing process, such as the temperature at which it occurs or the duration of the annealing process, can cause different resultant SOG materials to be formed. For instance, longer and/or hotter annealing processes can cause more “glassification” to occur, meaning that the resultant SOG material includes more Si—O—Si bonds within it, and thus, more closely resembles a pure silica. In some instances, the SOG may include dopants, such as Boron or Phosphorus. Thus, a SOG material may be a dielectric material that comprises Silicon, Oxygen, and at least one of Boron or Phosphorus. While a spin-coating technique may be commonly used for depositing SOG, embodiments herein may implement a slit coating technique, spray coating technique, or other types of coating techniques for depositing the SOG materials.

The SOG-based layers as described herein may be detected (versus a traditional glass core or other types of layers) in devices through XSEM/BSE scanning, which may show a contrast and/or texture difference between the SOG and silica glass (due to the vastly density and composition). Furthermore, elemental analysis (e.g., through EDX/XPS) may further identify the SOG material compared with silica glass, as the SOG material may include Boron, Phosphorus, or other dopants in certain embodiments, and may have carbonaceous signals resulting from either incorporation or decomposition of organic groups from parent organosilicate molecules. In addition, micro- or nano-porosity may also be featured within the SOG material as compared with silica glass.

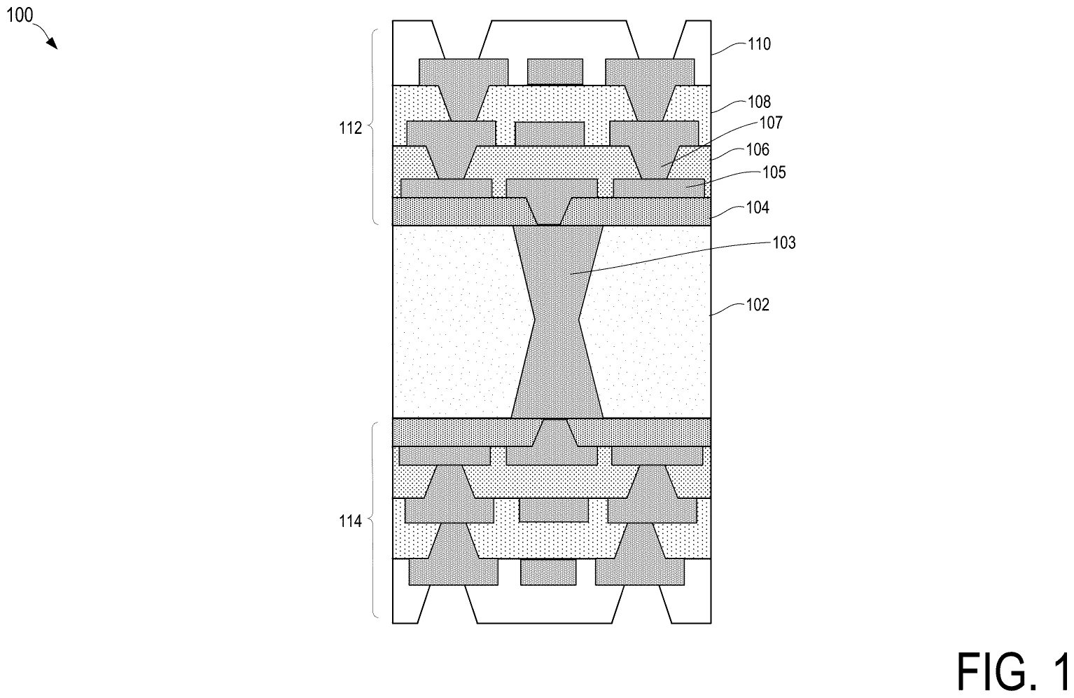

FIG. 1 illustrates an example cross-section of a package substrate 100 that includes a core 102 and BU layers 104, 106, 108 formed from a SOG material in accordance with embodiments of the present disclosure. In the example shown, the package substrate 100 also includes a BU layer 110 that is formed from an organic material, such as ABF. The core 102 includes a metal pillar 103 (which may also be referred to as a “via”) that interconnects the top side layers 112 of the package substrate 100 with the bottom side layers 114 of the package substrate 100. In addition, each BU layer of the package substrate 100 includes metal traces (e.g., 105) and metal vias (e.g., 107) connecting the layer to metal traces of an adjacent layer. Although the example pillars/vias are formed with particular shapes, certain embodiments may implement pillars having different shapes, e.g., with vertical sidewalls as shown in other figures and/or described below.

By utilizing SOG materials in one or more layers of a package substrate, one or more advantages may be seen over substrates that implement organic only layers and substrates with silica cores and organic BU layers. For example, CTE mismatches between the layers (and the issues seen because of those mismatches) can be minimized through the use of different SOG materials in the core and surrounding layers of the package substrate. For instance, in certain embodiments, each of the core 102, and the BU layers 104, 106, 108 may be formed using different SOG materials with different properties. For instance, in some embodiments, the core 102 may be formed from a first SOG material with a first CTE and the BU layers 104, 106, 108 may be formed from different SOG materials having a second, third, and fourth CTE, respectively that form for a gradient in CTE (in each layer) between the core 102 and the BU layer 110 (having a fifth CTE).

More generally, in embodiments herein, the core 102 may be formed from a first glass material composition (comprising Silicon and Oxygen, e.g., SiOx or SiO₂), the BU layer 104 may be formed from a second glass material composition that is different than the first glass composition of the core 102, the BU layer 106 may be formed from a third glass material composition that is different than the second glass composition of the BU layer 104, and so forth. The successive glass compositions may include substantially more dopants (e.g., Phosphorus or Boron) than the prior composition (e.g., the second glass composition of the BU layer 104 may include more P or B dopants than the first glass composition of the core 102). “Substantially more dopants” in a second layer may refer to more than 10× the amount of dopants of the first layer. In some embodiments, the first glass composition of the core 102 may include at most trace amounts of dopants (e.g., P or B), where “trace amounts” refers to less than 1% by elemental composition), while the second glass composition of the BU layer 104 (and additional BU layers, e.g., 106, 108) may include more than trace amounts of dopants (e.g., P or B).

Embodiments herein may accordingly allow for a higher potential in terms of TGV pitch scaling with novel manufacturing processes as described herein. Other additional advantages are described further below, and still other advantages may be readily apparent to those of skill in the art.

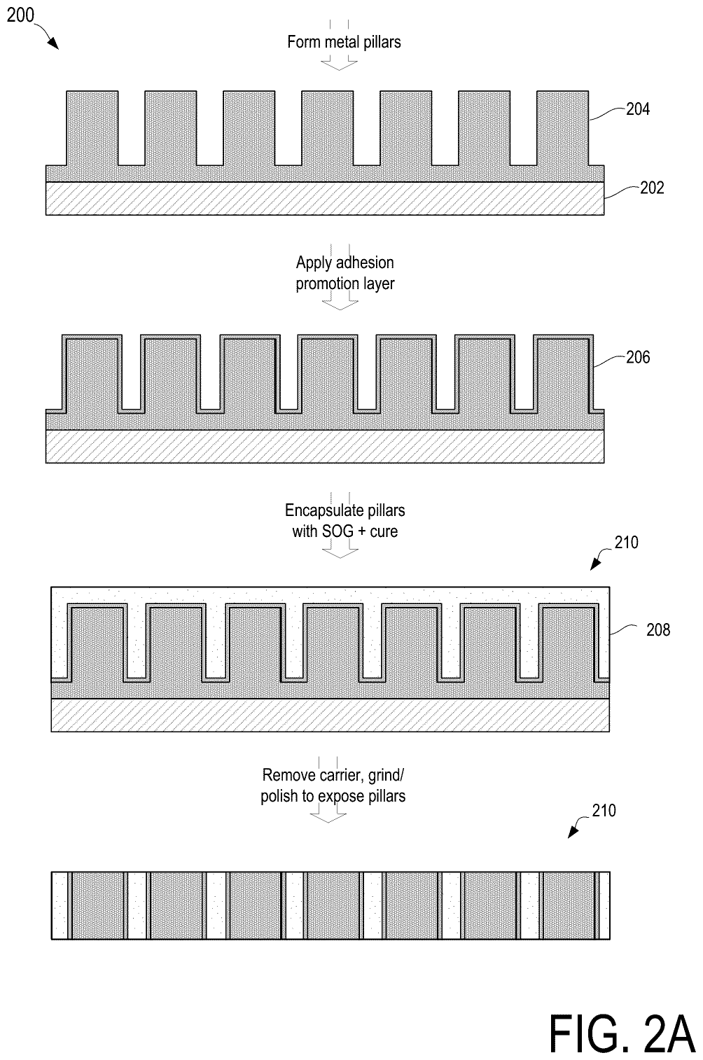

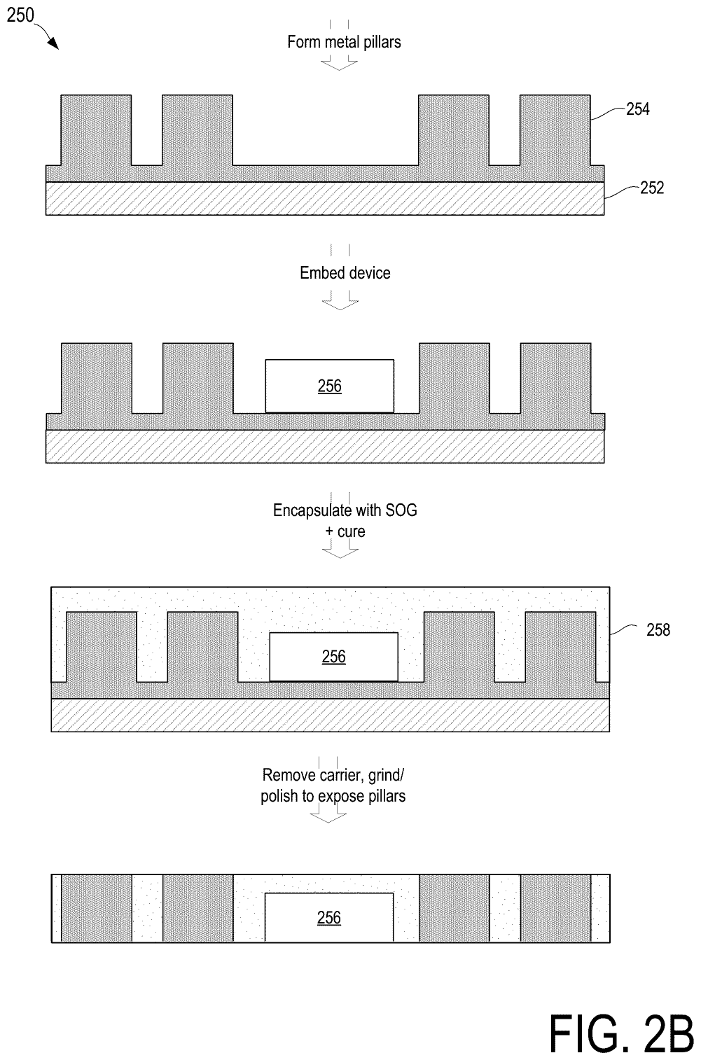

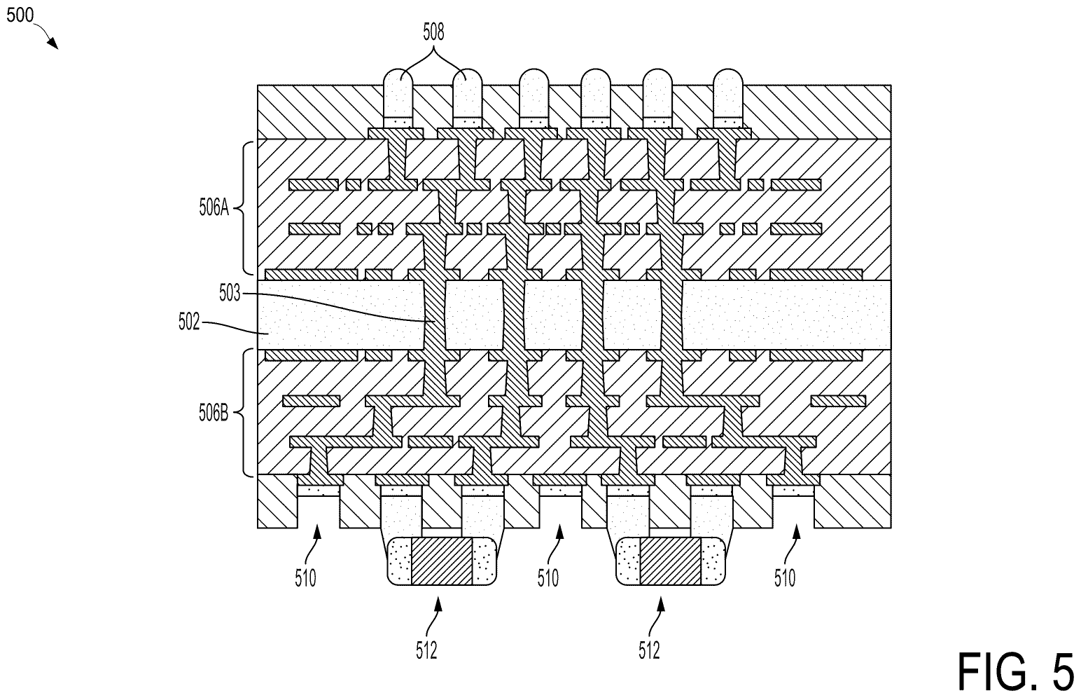

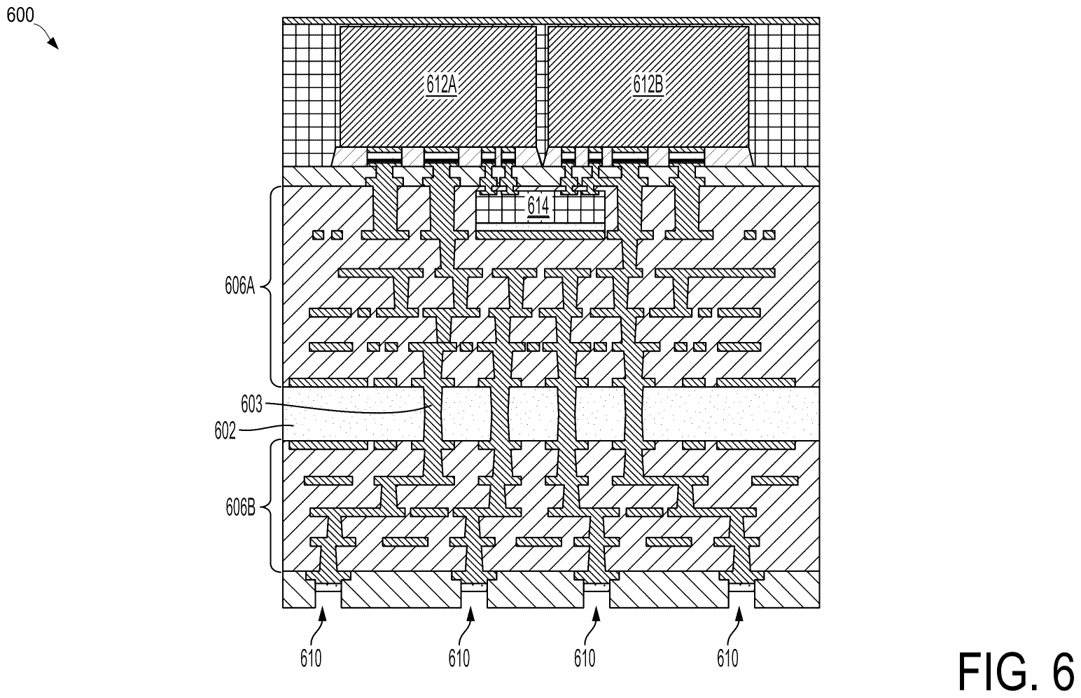

FIGS. 2A-2B illustrate example processes 200, 250 for manufacturing a package substrate core (e.g., 102) that is formed using a SOG material in accordance with embodiments of the present disclosure. The example processes shown may include additional, fewer, or different operations than those shown or described below. In some embodiments, one or more of the operations shown in FIGS. 2A-2B include multiple operations, sub-operations, etc. The illustrations of FIGS. 2A-2B may thus represent different stages in the manufacturing process. A core (e.g., 210) produced by the process 200 or 250 may be implemented in a package substrate such as those shown in FIGS. 5 and 6, or other embodiments described herein.

In silica core substrates, TGVs may be formed using a laser drill and wet etch process (sometimes referred to as a laser through hole (LTH) process) that forms the TGV holes. A seed material (e.g., Ti/Cu) can then be sputtered into the holes, followed by a blanket metal (e.g., Cu) deposition to fill the holes. Excessive metal from the blanket deposition can be removed using bulk etching and can be further processed by chemical mechanical planarization (CMP) (sometimes also referred to as “chemical mechanical polishing”) or other techniques to generate a flat surface. However, this process poses various challenges. For example, the TGV hole formation with LTH process may pose issues with scaling, e.g., due to LTH alignment capabilities. In addition, the LTH process may need to generate the holes with a necking taper (e.g., as shown in the pillar 103 of FIG. 1) to allow for a better line-of-slight for the seed sputtering step. However, this necking profile might not be ideal for power delivery or other reasons, and making the TGV holes straighter (i.e., the hole walls being more perpendicular to the top/bottom surfaces) can be costly as it might require expensive techniques such as atomic layer deposition (ALD) for depositing the seed material. Likewise, the removal of the excessive plating can be challenging as well, due to high cost and/or poor etching uniformity control. Furthermore, issues might arise during thermal cycling in the manufacturing process due to the CTE mismatch between the metal and the silica core.

Embodiments herein, however, provide a “Litho Via” (LiV) process that can be performed on a carrier layer (e.g., glass) to form the metal pillars of the TGV and then utilizes a Spin-on-Glass (SOG) process to encapsulate the pillars to form the substrate core. The newly formed TGV core can then be de-bonded from the carrier layer for additional downstream processing, e.g., forming build-up layers on top and bottom of the core. The LiV process described herein may provide extended scalability as the TGV may be defined by the lithography approach, meaning that high aspect ratio pillar formation may be had with minimal CD variations and very straight pillars with controllable taper profiles. Additionally, in some embodiments, pillar roughening may be implemented or an adhesion promotor (AP) material can be applied to the pillars for improved adhesion/stress relief buffering to the SOG material to improve reliability of the core. Further, because the pillars are formed before being encapsulated with the SOG material, there may be additional possibilities for embedding additional features within the core. In addition, pillar uniformity on the carrier can be very good as it can be based on Copper-dry film resist (DFR) planarization in certain embodiments. Moreover, the selection of the SOG material can enable CTE matching between the SOG and the metal pillars to reduce overall CTE mismatching within the core (or between the core and metal traces on the core).

Turning to FIG. 2A, the example process 200 begins by forming metal (e.g., Copper) pillars 204 on a carrier substrate 202 (e.g., glass). In some embodiments, a seed material may be first deposited on the substrate 202 to promote the deposition/growth of the metal pillars 204. The pillars 204 may be formed using lithography and plating techniques, including masking, etching, etc. with photoresist materials (e.g., dry film resist (DFR) or liquid photoresist (LPR)), and accordingly, the pillars 204 may be formed in a substantially vertical orientation on the carrier substrate 202. Because of this, the sidewalls of the pillars 214 will be substantially perpendicular to the top and bottoms sides the package substrate core that results from the process 200 (e.g., the sidewalls of the pillars and the top/bottom sides of the core may form an angle between approximately 85-95°).

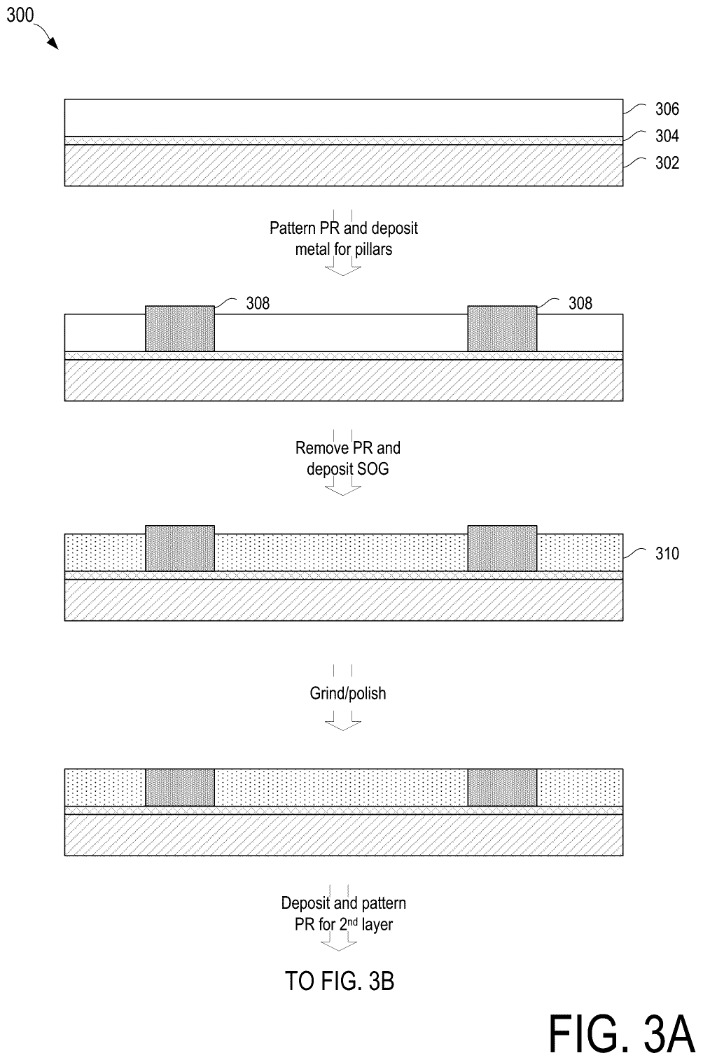

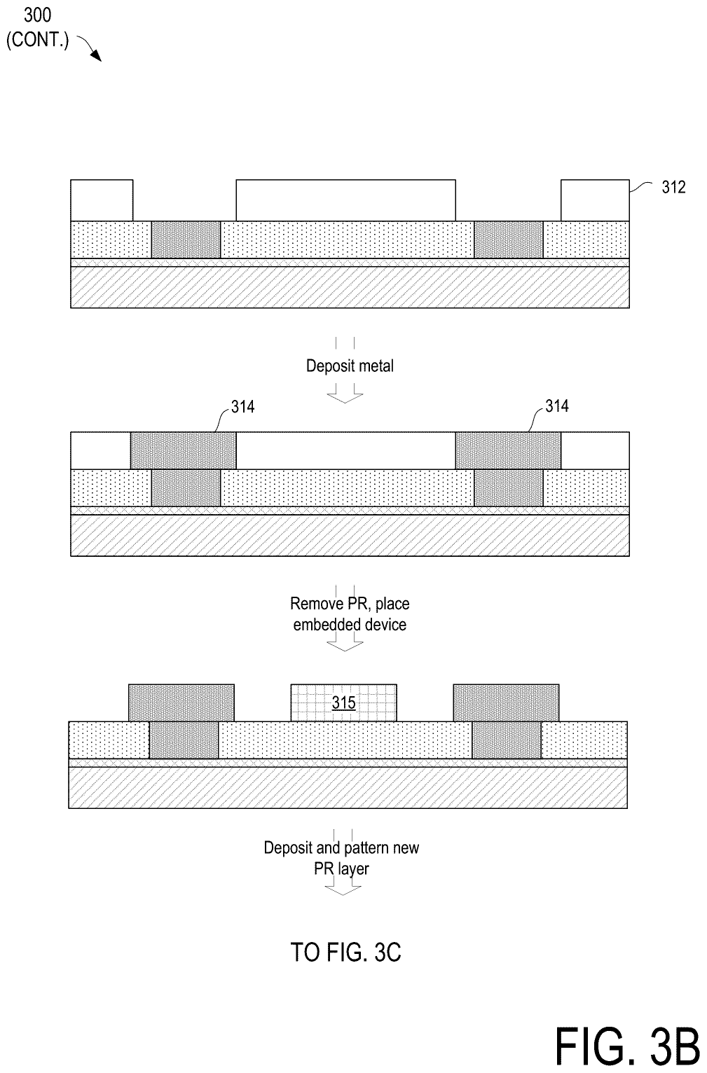

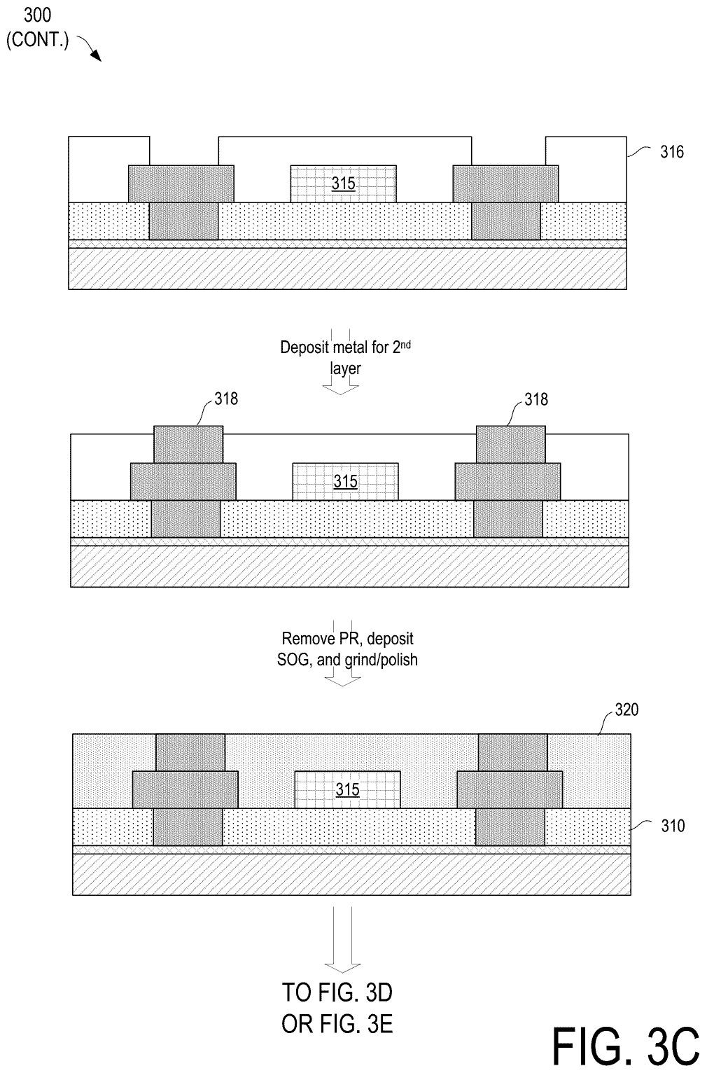

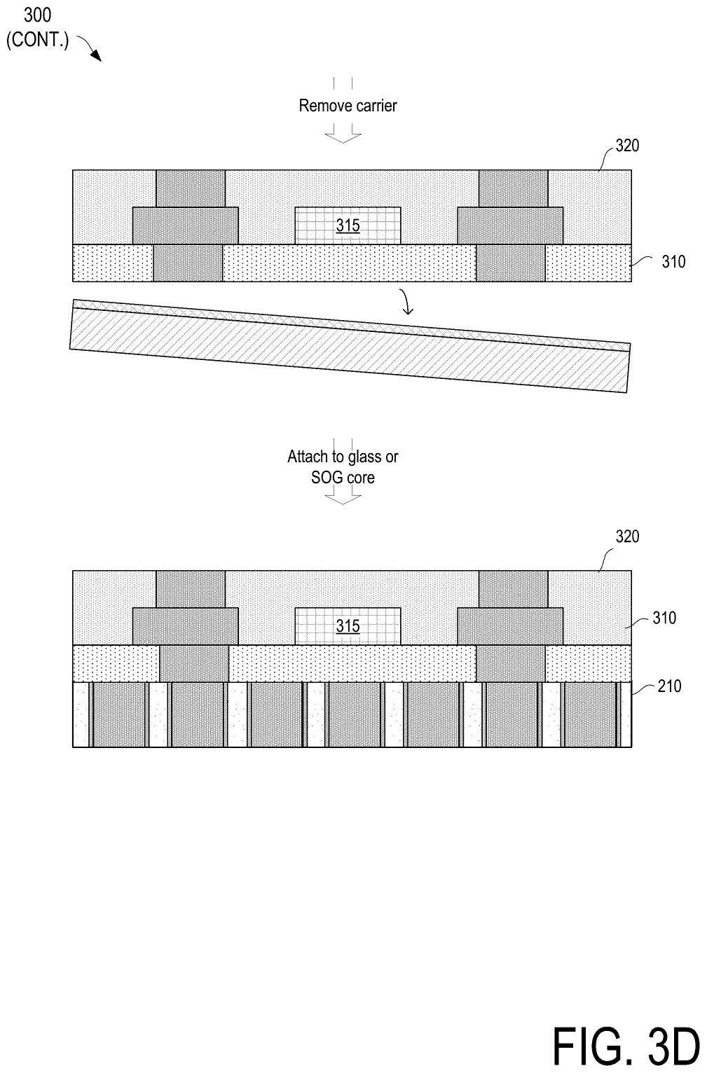

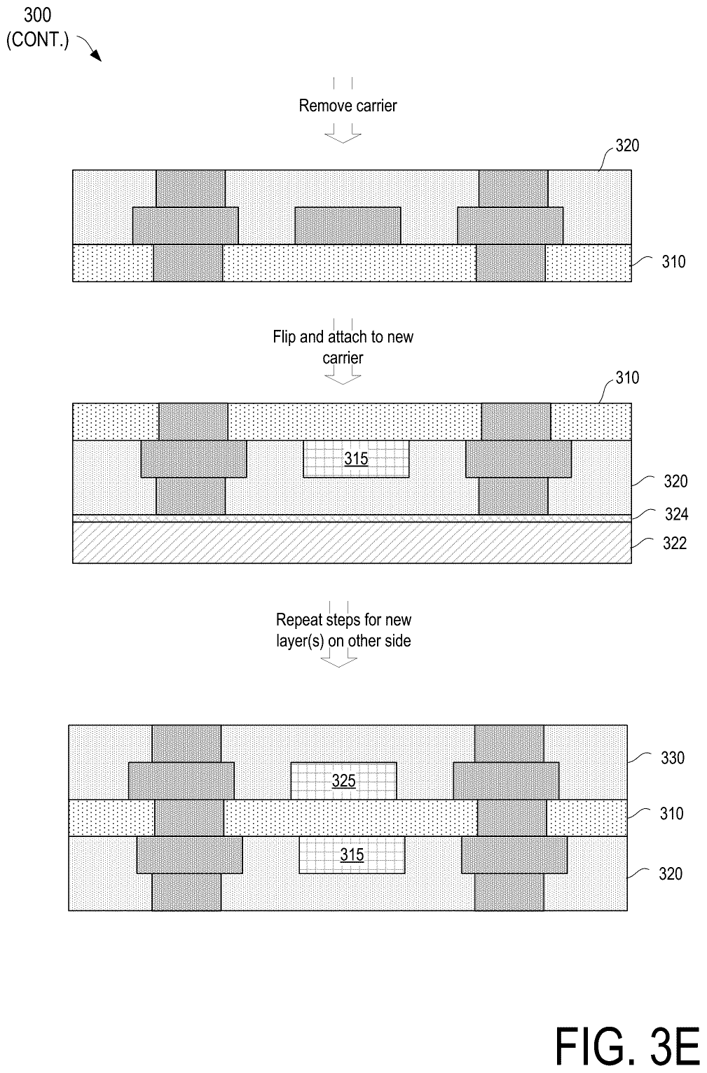

Further, by forming the pillars 204 in this manner, future generation size/scaling may be achievable. An additional layer 206 (e.g., SiO2 or SiNx) is then formed in a conformal manner on the surface of the pillars 203. The layer 206 may include on or more of an adhesion promoter material (e.g., SiO2 or SiNx) or a thermal protection material (or both). A liquid layer 208 is then deposited in a manner that encapsulates the pillars 204 as shown to form a material stack 210. The liquid layer 208 may be a SOG material as described above or may be a liquid containing glass nanoparticles. In some embodiments, however, the layer 208 may not encapsulate the pillars 204, and may instead leave top portions of the pillars 204 exposed (e.g., as shown in FIG. 3A). The liquid layer may then be cured or annealed to harden the SOG material. The carrier substrate 202 may then be removed from the stack 210 and each side of the stack 210 may be ground or otherwise planarized (e.g., using chemical mechanical integrated package (CMP) or other suitable techniques) to yield a substrate core with the pillars accessible on either side as shown in the last drawing of FIG. 2A. The planarization process may make each side of the stack 210 substantially parallel with one another (e.g., within +/−5° of being parallel).

The above process may allow for further TGV scaling for future substrate package needs (e.g., as scales continues to decrease), and also allows for better pillar yields due to the lithographic processes used to form the pillars. In addition, as described above, the use of SOG as described can allow for decreased CTE mismatch between the resulting package substrate core and other layers that can then be formed thereon, allowing for better package reliability and warpage control.

Furthermore, the above process may allow for embedded devices, e.g., bridge circuitry or other logic/circuit components, to be placed inside the substrate core. FIG. 2B illustrates an example process 250 for embedding a device 256 using a similar process to the one described above. In the example shown, pillars 254 are formed on a carrier substrate 252, e.g., in a similar manner as described above with respect to the pillars 254. The carrier substrate 254 may likewise be implemented in the same or similar manner as the carrier substrate 202.

The device 256 may then be embedded. For instance, in the example shown, the device 256 is placed within a recess of the pillar formations, and then the pillars 254 and device 256 are encapsulated with a SOG material 258, which is then cured and planarized (e.g., ground or polished via CMP) in the same or similar manner as described above. In other embodiments, however, the device 256 may be embedded after the deposition of the SOG material 258, but before the curing/annealing of the SOG material. In some embodiments, a portion of the SOG material layer 258 may be first deposited and cured/annealed, and the device 256 may then be embedded before depositing and curing/annealing the remainder of the SOG material layer 258. The device 256 may include any suitable logic or other circuitry.

FIGS. 3A-3D illustrate an example process 300 for manufacturing build-up (BU) layers of a package substrate in accordance with embodiments of the present disclosure. The example processes shown may include additional, fewer, or different operations than those shown or described below. In some embodiments, one or more of the operations shown in FIGS. 3A-3D include multiple operations, sub-operations, etc. The illustrations of FIGS. 3A-3D may thus represent different stages in the manufacturing process. BU layers produced by the process 300 may be implemented in a package substrate such as those shown in FIGS. 5 and 6, or other embodiments described herein.

The example process 300 involves a lithography-based metal plating and spin-on-glass (SOG) encapsulation, which can provide a better scalability, warpage control and patterning profiles when compared with traditional organic BU layers, and also provides the possibility of device embedding within the BU layers. Although the process 300 is illustrated as being carried out on a carrier substrate that is later removed (e.g., as shown in FIG. 3D), it will be understood that aspects of the process 300 may be implemented on a substrate package core (e.g., one produced by the process 200 with a SOG material as described above or by other methods, or a silica core with vias made by a LTH process) instead of the carrier substrate 302. In this way, the build-up layers may be fabricated on one or both sides of a glass core. In some embodiments, the layer 310 shown in FIGS. 3A-3D may be implemented as the core of the package substrate.

In current techniques, organic BU layers are formed using a dry SAP process, which uses dielectric dry film and laser drilled vias that are dry desmeared in plasma. This can have some disadvantages, however. For example, the dry SAP process may be quite costly, and can put strain in the BU via cleaning (since it is a challenging process, especially when future via size scaling is considered). Additionally, as described above, traditional organic BU layer materials (e.g., ABF) may have a relatively low CTE compared to dielectric dry films, but may still induce warpage concerns due to the CTE mismatch with metal (e.g., Copper) plating. Using low Dk/df ratio material (where Dk refers to a dielectric constant and df refers to a dissipation factor or loss tangent) can impact dry film formulation, and it may be a balancing act to produce good electrical property films with low CTE.

Embodiments herein can provide one or more benefits over traditional BU layer fabrication processes. For example, embodiments herein may provide better critical dimension (CD, which may, for a via, refer to the top/bottom diameter and height), taper, and overlay control for the BU layer vias. Furthermore, a descum process for un-filled vias with embodiments of the present disclosure may be easier than with filled BU vias. And as described above, the SOG material used for the BU layers can be tailored to each layer's localized CTE to minimize any CTE mismatch between plated metal pillars or traces and the SOG encapsulation. Moreover, SOG encapsulation as described herein may help to reduce total package warpage and enable a tighter thermal compression bonding (TCB, which may refer to an attachment technique that can be used for die-to-substrate bonding) attach window as pitch scaling is decreased in future implementations.

Turning to FIG. 3A, the process 300 begins with an unpatterned stack that includes a carrier substrate 302, debond film layer 304, and photoresist layer 306. The debond film layer 302 may be formed from a material that allows the carrier substrate 302 to be reused in other future processes. The debond film layer 302 may be an adhesive layer that is directly on the carrier substrate 202, and in some instances, may also include a responsive layer that is on the adhesive layer. During the debond process, a laser, a thermal, or other triggering method can be used to cause a decrease in the adhesion of the response layer and the material stack formed on the carrier will be removed from the carrier. The photoresist layer 306 may be formed from a dry film resist (DFR) material, liquid photoresist (LPR), or other suitable type of photoresist material. The photoresist layer 306 is then patterned and metal pillars 308 are formed (e.g., by plating or other deposition method) as shown in the second image of FIG. 3A. In some embodiments, an adhesion promotion layer (e.g., SiO2, SiNx) or thermal protection layer may also be deposited on the surface of the pillars (similar to shown in FIG. 2 and described above).

Next, the photoresist layer 306 is removed and a layer 310 comprising a SOG material (or other liquid containing glass nanoparticles) is deposited to encapsulate the pillars 308. In the example shown, the tops of the pillars are left exposed after the deposition of the layer 310. However, in other embodiments, the pillars 308 may be fully encapsulated by the SOG material layer. The layer 310 is then cured or annealed to harden it, and the top of the stack is then ground or polished (e.g., via CMP or another similar process) to flatten the top surface of the stack. This general process can then be repeated for additional BU layers.

For instance, turning to FIG. 3B, another layer of photoresist material layer 312 is deposited and patterned as shown in the top image of FIG. 3B, and then metal traces 314 are plated or otherwise deposited as shown in the second image of FIG. 3B. The photoresist layer 312 is then removed, a device 315 is placed for embedding within the layer. The device 315 may include any suitable logic circuitry or one or more other types of circuitry/circuit components.

Turning to FIG. 3C, another photoresist layer 316 is then deposited and patterned as shown in the top image of FIG. 3C, so that metal can be deposited for additional pillars 318. The photoresist layer 316 is then removed, and a layer 320 comprising a SOG material (or other liquid containing glass nanoparticles) is deposited to encapsulate the traces 314, device 315, and pillars 318. As above, the tops of the pillars may be left exposed after the deposition of the layer 320 or may be fully encapsulated by the SOG material layer 320. The material used for the layer 320 may be the same or different from the material used for layer 310. For example, the respective layers may be selected or tuned for close CTE matching, or for another purpose. The layer 320 is then cured or annealed to harden it, and the top of the stack is again ground or polished (e.g., via CMP or another similar process) to flatten the top surface of the stack.

The process shown in FIGS. 3A-3C can then be repeated to fabricate additional BU layers using SOG materials. For instance, additional BU layers may be fabricated on the layer comprising the SOG material 320. The additional BU layers may be fabricated using different SOG materials from either 310 or 320. Once the BU layers of one side are complete, the carrier substrate may be removed, e.g., as shown at the top of FIG. 3D or FIG. 3E. The resulting stack can then be bonded to a glass-based core, such as a silica substrate core or a SOG-based substrate core (e.g., the core 210 fabricated using the example process 200 above), as shown in FIG. 3D. In some embodiments, the first layer formed in the process (e.g., the one comprising the SOG material 310) may function as a core for the package substrate, and the stack may then be flipped as shown in FIG. 3E to fabricate additional BU layers on the backside of the stack. For instance, as shown in FIG. 3E, the stack is flipped so that a new carrier substrate 322 and debond layer 324 can be attached to the side opposite from where the carrier substrate 302 and debond layer 304 were attached. Then, BU layers (e.g., the one comprising the SOG material 330 and an embedded device 325) can be fabricated on the backside of the stack in the same manner as shown in FIGS. 3A-3C. The substrate 322 and debond layer 324 may be implemented in the same or similar manner as the substrate 302 and debond layer 304 (e.g., the same or similar materials). A passivation layer (e.g., a solder resist layer) can then be patterned on both surfaces of the stack. The passivation/solder resist layer may be formed using any suitable passivation dielectric materials.

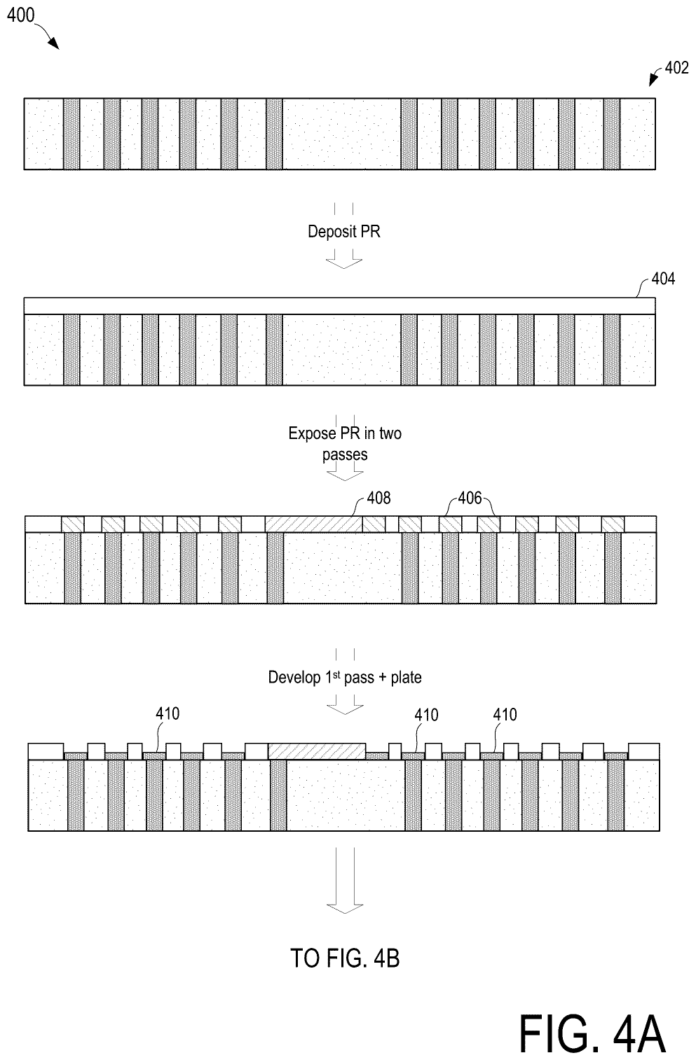

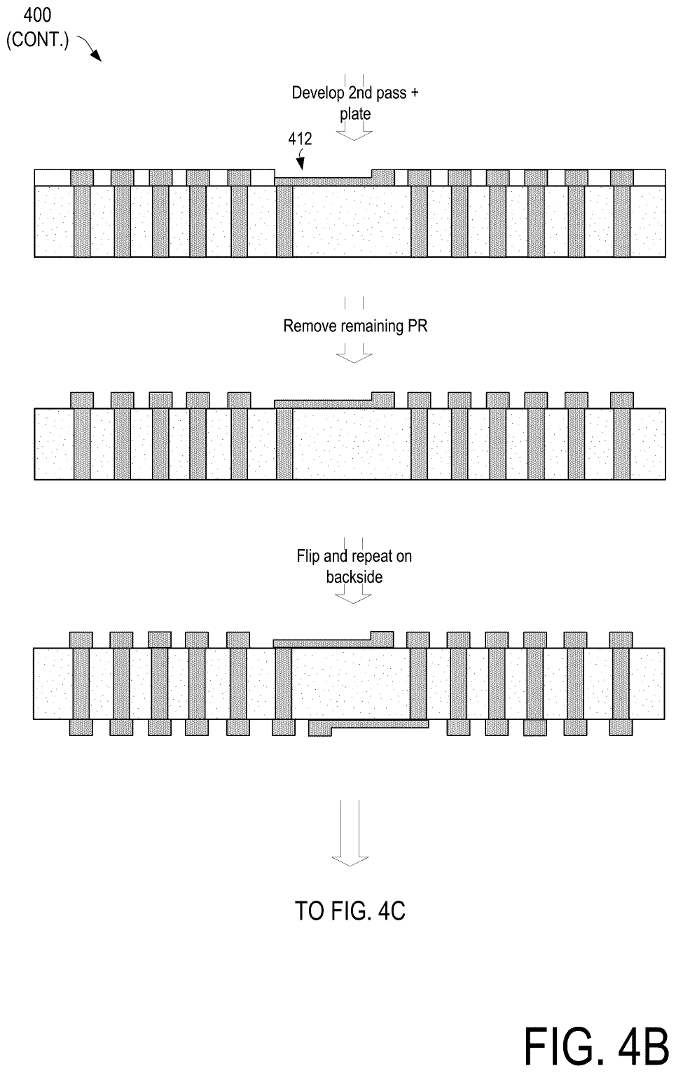

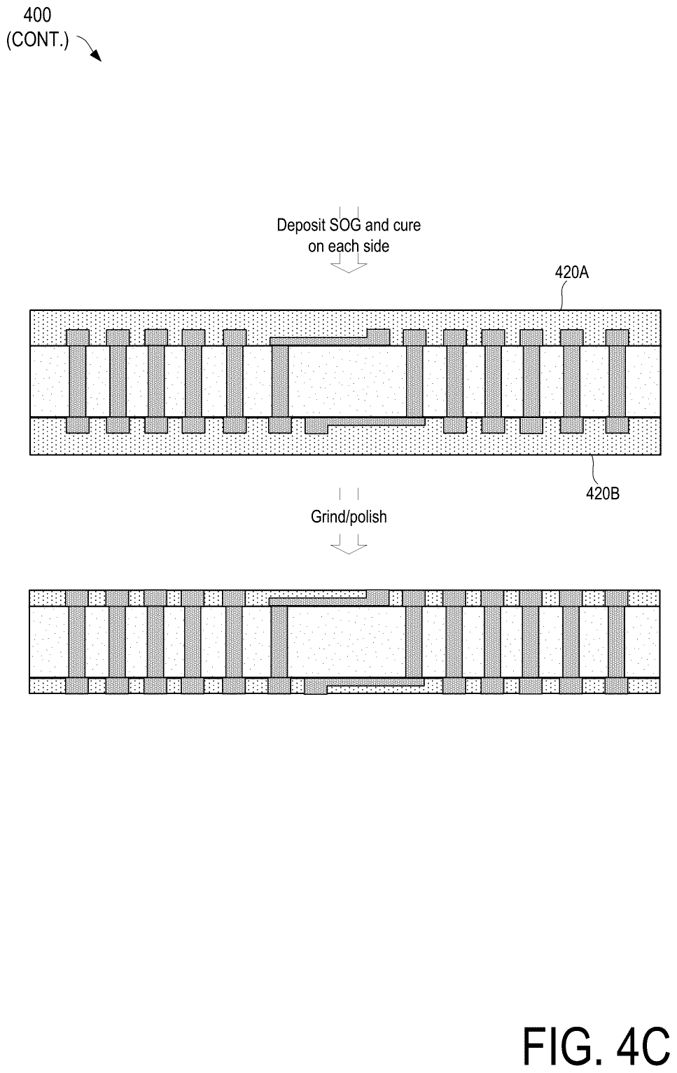

FIGS. 4A-4C illustrate another example process 400 for manufacturing build-up (BU) layers of a package substrate in accordance with embodiments of the present disclosure. The example processes shown may include additional, fewer, or different operations than those shown or described below. In some embodiments, one or more of the operations shown in FIGS. 4A-4C include multiple operations, sub-operations, etc. The illustrations of FIGS. 4A-4C may thus represent different stages in the manufacturing process. Further, aspects of the process 400 may be implemented using a substrate package core that is produced by the process 200 (i.e., with a SOG material, as described above or by other methods) or using a glass core with vias made by a LTH process. Moreover, aspects of the process 400 may be implemented to produce a package substrate such as those shown in FIGS. 5 and 6, or other embodiments described herein.

In current package substrates with glass cores, metal (e.g., Copper) traces may be patterned onto the core, but these traces are at a high risk to delaminate due to stress caused by the CTE mismatch between the metal and the glass. Some solutions may accordingly utilize an organic buffer layer between the metal traces and the glass core to decouple the CTE mismatch, but electrical performance can suffer due to the need to route vias in the core through the additional buffer layer and land onto LTH pads. Because LTH is designed for low diameter, low pitch holes, it may provide little margin to land a via. Consequently, substrates with glass cores and buffer layers have additional process steps and signal routing lengths, and thus suffer from higher cost and worse electrical performance.

In the example process 400, however, high density metal trace routing for a build-up layer may be implemented directly onto a glass-based substrate core (e.g., a traditional glass core or one manufactured according to the example process 200 above) in a two-step, “dual lithography” or “dual litho” approach. Then, SOG may be applied (to encapsulate the traces) and then cured or annealed to “anchor” the metal traces in place. Metal pads in the layer can then revealed by a grind/polish step. This general process may be repeated for additional BU layers. In certain embodiments, the SOG may be co-annealed with the metal traces to minimize the stress in the process, as the Si—O network in the SOG material forms during the metal expansion. Modulation of the stress can be achieved with a thermal profile that can tailor time/temp/ramp conditions in the cure/annealing process to modulate the Si—O network formation for different temperatures to achieve stress profiles that are stable after cooling.

This dual lithography and SOG approach for manufacturing BU layers of a substrate may yield one or more advantages over current substrates. For example, strong electrical performance can be seen, e.g., due to the substantially vertical sidewalls of the vias in the BU layers, and no metal roughening needed for adhesion. In addition, the SOG that is used for each BU layer can be tailored to the package substrate architecture and materials, e.g., various compositions (typically by controlling ratios of various organosilicate) can modulate the Porosity, Modulus, and Dielectric Constant of the resulting material. In addition, the routing in the first BU layer (M0) on a low TTV glass-based core can enable fine line/spacing (FLS, which may refer to a relatively small spacing between metal traces of a particular layer) and possible layer-pair reduction.

Referring to FIG. 4A, a glass-based core 402 is formed, e.g., through the process 200 described above for a SOG-based core layer or by a traditional LTH process in a glass core layer. A layer of photoresist 404 is then deposited on the core 402 and exposed in two passes. That is, the photoresist is exposed in different amounts (e.g., intensities and/or durations of ultraviolet light) in different regions (e.g., 406, 408). The different exposures in the respective regions thus causes different development processes to be needed to remove the photoresist in the regions. Then, the photoresist is developed in a first pass to remove the regions 406 and metal 410 is deposited or plated as shown at the bottom of FIG. 4A. The metal 410 may be a portion of pads that will be accessible to other layers of the package substrate.

The photoresist is then developed in a second pass to remove the region 408 and additional metal (e.g., 412) is deposited or plated as shown at the top image of FIG. 4B. The portion 412 of the deposited metal may form traces within the build-up layer (e.g., to provide interconnections between different vias/pads of the layer), while the other portion of the metal deposited may provide the remainder of the pads that are accessible to other layers of the package substrate. The remaining photoresist is then removed, the stack is flipped and the process is repeated to plate the backside of the stack in the same manner (e.g., as shown in the bottom image of FIG. 4B).

Next, a SOG material 420 is deposited each side of stack and then cured/annealed. IN some embodiments, the SOG material may be deposited and cured/annealed on a first side (e.g., 420A) before depositing and curing/annealing the SOG material on the other side (e.g., 420B). The annealed SOG material 420 may function to “anchor” the metal traces/pads to surface of the core 402. The process 400 may accordingly not require that the metal traces be roughened for adhesion purposes. However, in some embodiments, an intermediate adhesion layer (e.g. Ti, SiNx, AlN, etc.) may be deposited on the core to further promote adhesion between the traces/pads and the surface of the core 402. In certain embodiments, each side of SOG material 420A, 420B may be deposited and cured/annealed in one step or may be performed in several steps to build up the layer thickness. Each side of the substrate stack may then be ground or polished (e.g., by CMP) to reveal the metal pads.

In some embodiments, another heating or curing step may then be performed, which could allow for a higher CMP removal rate. That is, the SOG material may be only partially cured before the grinding/polishing is performed, followed by another additional curing of the SOG material post-grind/polish. This may be beneficial in certain instances because a flatter surface may be more easily achieved with CMP when performed on a partially cured SOG material versus a fully-cured SOG material. The above steps may be repeated to provide for additional, subsequent layers.

One advantage of implementing SOG BU layers as described above is the relatively high modulus of the SOG material relative to an organic dielectric alternative. In other words, replacing organic BU layers with SOG-based BU layers may help to reduce package warpage. One concern with SOG is stress-induced cracking; however, certain embodiments may incorporate organic functional groups in the SOG material and use a modulated Si—O network density from the cure step to minimize this potential issue.

FIG. 5 illustrates an example package substrate 500 that may incorporate one or more aspects of the present disclosure. The example package substrate 500 includes a core 502 that is manufacturing using a spin-on glass (SOG) material, which can help to provide rigidity to the package substrate 500 and improve potential CTE mismatches as described above. Build-up layers 506 are formed on the top and bottom sides of the core 502, with build-up layers 506A on the top side of the glass core 502 and the build-up layers 506B on bottom side of the core 502.

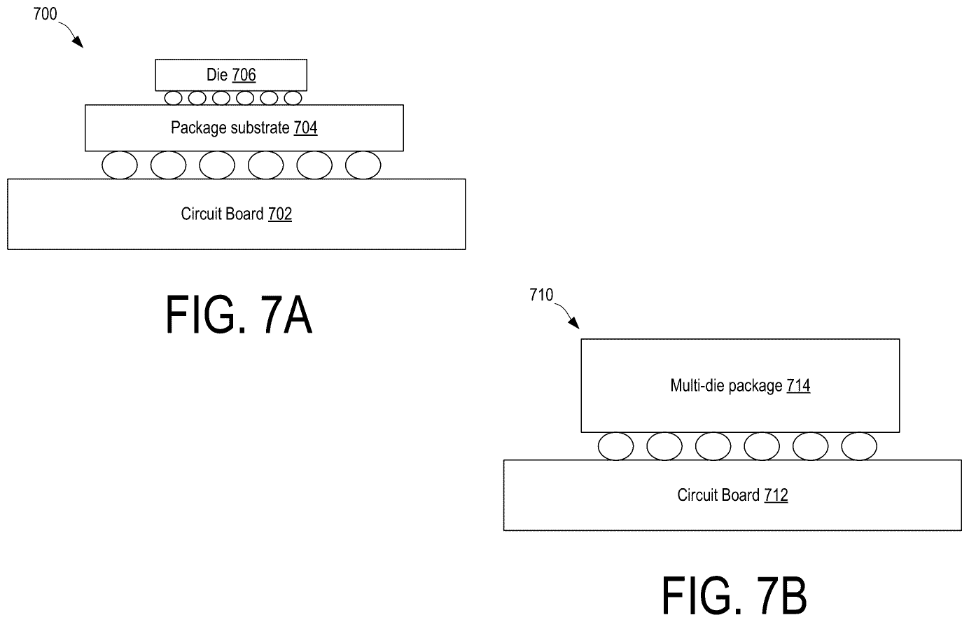

The layers 506 may be made from a traditional organic BU material in certain embodiments, while other embodiments may implement layers 506 made from a SOG material as described above. The layers 506 include metal pillars, vias, and/or traces as shown to electrically couple the solder bumps 508 at the top of the package substrate 500 with the pads 510 at the bottom of the substrate. In certain instances, for example, an integrated circuit die may be coupled to a top side of the package substrate 500 and connect to the solder bumps 508, and the package substrate 500 may be coupled to a circuit board (e.g., a motherboard, main board, etc.) via the pads 510 at the bottom of the package substrate 500. For instance, the package substrate 500 may be incorporated into the system 700 of FIG. 7A as the package substrate 704. The package substrate 500 also includes land side capacitors 512 coupled on a bottom side of the package substrate 500.

FIG. 6 illustrates an example multi-die package 600 that may incorporate one or more aspects of the present disclosure. The multi-die package 600 includes build-up layers 606 formed on the top and bottom sides of the core 602, which may be made from a SOG material as described herein, with build-up layers 606A formed on the top side of the core 602 and the build-up layers 606B formed on bottom side of the core 602. The build-up layers 606 may be formed from traditional organic materials, or may be formed from a SOG material as described herein. The layers 606 include metal pillars, vias, and/or traces as shown to electrically couple the integrated circuit (IC) dies 612 at the top of the multi-die package 600 with the pads 610 at the bottom of the package 600.

In addition, there is a bridge component 614 located in the build-up layers 606A that electrically couples the first IC die 612A with the second IC die 612B. The bridge component 614 may include passive and/or active components to interconnect the IC dies 612. The bridge component 614 may be an Intel® embedded multi-die interconnect bridge (EMIB) in certain embodiments. In certain instances, the multi-die package 600 may be coupled to a circuit board (e.g., a motherboard, main board, etc.) via the pads 610 at the bottom of the package 600. For instance, the package 600 may be incorporated into the system 710 of FIG. 7B as the multi-die package 714.

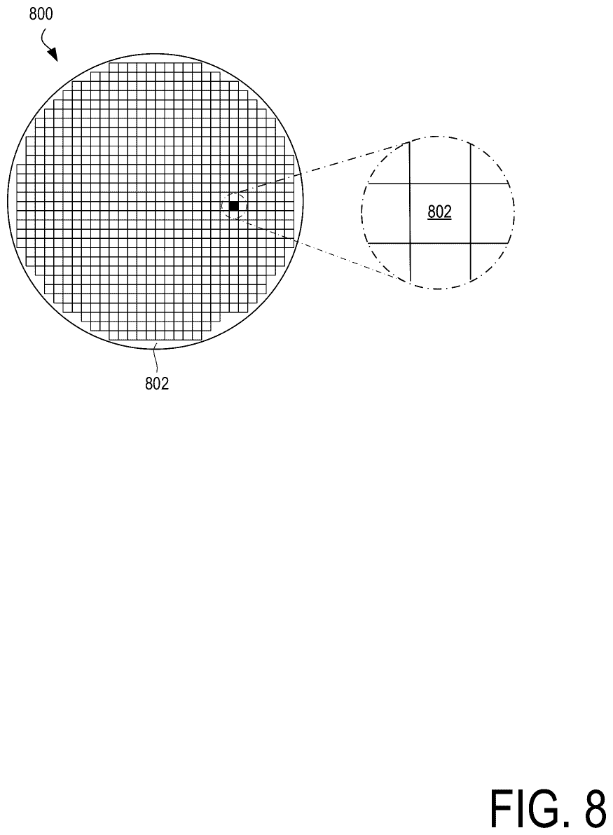

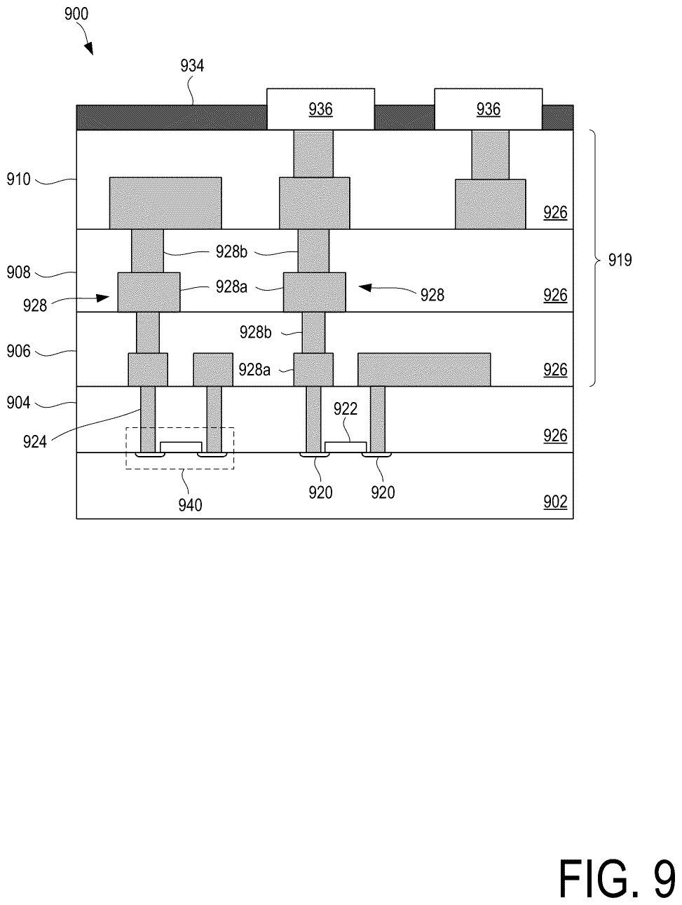

FIGS. 7A-7B illustrate example systems 700, 710 that may incorporate the SOG-based architectures described herein. The example system 700 of FIG. 7A includes a circuit board 702, which may be implemented as a motherboard or main board of a computer system in some embodiments. The example system 700 also includes a package substrate 704 with an integrated circuit die 806 attached to the package substrate 704. The die 706 may be a packaged or unpacked integrated circuit product that includes one or more integrated circuit dies (e.g., the die 802 of FIG. 8, the integrated circuit device 900 of FIG. 9) and/or one or more other suitable components. The die 706 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the die 706 can comprise one or more additional active or passive devices such as capacitors, decoupling capacitors, resistors, inductors, fuses, diodes, transformers, sensors, electrostatic discharge (ESD) devices, and memory devices. In addition to comprising one or more processor units, the die 706 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. The package substrate 704 may provide electrical connections between the die 706 and the circuit board 702.

Similar to the system 700, the system 710 also includes a circuit board 712, which may be implemented as a motherboard or main board of a computer system in some embodiments. The system 710 also includes a multi-die package 714, which includes multiple integrated circuits/dies (e.g., 706), and interconnections between the dies in one or more metallization layers. The multi-die package 714 may include, for example, one or more silicon interposers, one or more silicon bridges embedded in the package substrate (e.g., an Intel® embedded multi-die interconnect bridge (EMIB)), or combinations thereof.

The main circuit boards 710, 712 may provide electrical connections to other components of a computer system, e.g., memory, storage, network interfaces, peripheral devices, power supplies, etc. The main circuit board may include one or more traces and circuit components to provide interconnects between such computer system components.

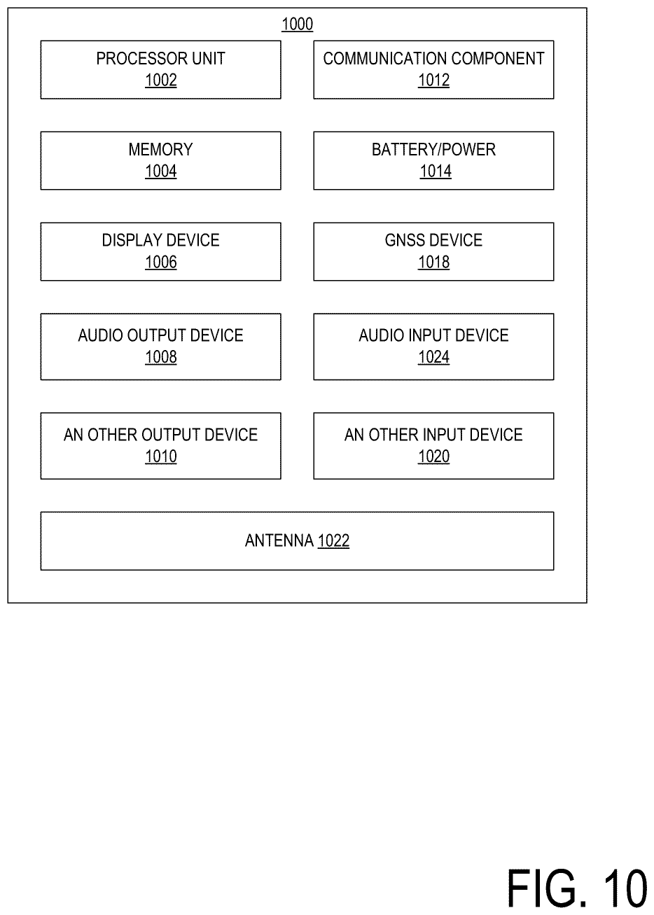

FIG. 8 is a top view of a wafer 800 and dies 802 that may be implemented in or along with any of the embodiments disclosed herein. The wafer 800 may be composed of semiconductor material and may include one or more dies 802 having integrated circuit structures formed on a surface of the wafer 800. The individual dies 802 may be a repeating unit of an integrated circuit product that includes any suitable integrated circuit. After the fabrication of the semiconductor product is complete, the wafer 800 may undergo a singulation process in which the dies 802 are separated from one another to provide discrete “chips” of the integrated circuit product. The die 802 may include one or more transistors (e.g., some of the transistors 940 of FIG. 9, discussed below), supporting circuitry to route electrical signals to the transistors, passive components (e.g., signal traces, resistors, capacitors, or inductors), and/or any other integrated circuit components. In some embodiments, the wafer 800 or the die 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 802. For example, a memory array formed by multiple memory devices may be formed on a same die 802 as a processor unit (e.g., the processor unit 1002 of FIG. 10) or other logic that is configured to store information in the memory devices or execute instructions stored in the memory array.

FIG. 9 is a cross-sectional side view of an integrated circuit device 900 that may be included in any of the embodiments disclosed herein. One or more of the integrated circuit devices 900 may be included in one or more dies 802 (FIG. 8). The integrated circuit device 900 may be formed on a die substrate 902 (e.g., the wafer 800 of FIG. 8) and may be included in a die (e.g., the die 802 of FIG. 8). The die substrate 902 may be a semiconductor substrate composed of semiconductor material systems including, for example, n-type or p-type materials systems (or a combination of both). The die substrate 902 may include, for example, a crystalline substrate formed using a bulk silicon or a silicon-on-insulator (SOI) substructure. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit device 900 may be used. The die substrate 902 may be part of a singulated die (e.g., the dies 802 of FIG. 8) or a wafer (e.g., the wafer 800 of FIG. 8).

The integrated circuit device 900 may include one or more device layers 904 disposed on the die substrate 902. The device layer 904 may include features of one or more transistors 940 (e.g., metal oxide semiconductor field-effect transistors (MOSFETs)) formed on the die substrate 902. The transistors 940 may include, for example, one or more source and/or drain (S/D) regions 920, a gate 922 to control current flow between the S/D regions 920, and one or more S/D contacts 924 to route electrical signals to/from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 9, a transistor 940 may include a gate 922 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 940 along the source-channel-drain direction, the gate electrode may consist of a U-shaped structure that includes a bottom portion substantially parallel to the surface of the die substrate 902 and two sidewall portions that are substantially perpendicular to the top surface of the die substrate 902. In other embodiments, at least one of the metal layers that form the gate electrode may simply be a planar layer that is substantially parallel to the top surface of the die substrate 902 and does not include sidewall portions substantially perpendicular to the top surface of the die substrate 902. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of individual transistors 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the integrated circuit device 900.

The interconnect structures 928 may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuit devices having more or fewer interconnect layers than depicted.

In some embodiments, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page from the perspective of FIG. 9. The vias 928b may be arranged to route electrical signals in a direction of a plane that is substantially perpendicular to the surface of the die substrate 902 upon which the device layer 904 is formed. In some embodiments, the vias 928b may electrically couple lines 928a of different interconnect layers 906-910 together.

The interconnect layers 906-910 may include a dielectric material 926 disposed between the interconnect structures 928, as shown in FIG. 9. In some embodiments, dielectric material 926 disposed between the interconnect structures 928 in different ones of the interconnect layers 906-910 may have different compositions; in other embodiments, the composition of the dielectric material 926 between different interconnect layers 906-910 may be the same. The device layer 904 may include a dielectric material 926 disposed between the transistors 940 and a bottom layer of the metallization stack as well. The dielectric material 926 included in the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910.

A first interconnect layer 906 (referred to as Metal 1 or “M1”) may be formed directly on the device layer 904. In some embodiments, the first interconnect layer 906 may include lines 928a and/or vias 928b, as shown. The lines 928a of the first interconnect layer 906 may be coupled with contacts (e.g., the S/D contacts 924) of the device layer 904. The vias 928b of the first interconnect layer 906 may be coupled with the lines 928a of a second interconnect layer 908.

The second interconnect layer 908 (referred to as Metal 2 or “M2”) may be formed directly on the first interconnect layer 906. In some embodiments, the second interconnect layer 908 may include via 928b to couple the lines 928 of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit device 900 (i.e., farther away from the device layer 904) may be thicker that the interconnect layers that are lower in the metallization stack 919, with lines 928a and vias 928b in the higher interconnect layers being thicker than those in the lower interconnect layers.

The integrated circuit device 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to external devices. For example, solder bonds may be formed on the one or more conductive contacts 936 to mechanically and/or electrically couple an integrated circuit die including the integrated circuit device 900 with another component (e.g., a printed circuit board or a package substrate, e.g., 112). The integrated circuit device 900 may include additional or alternate structures to route the electrical signals from the interconnect layers 906-910; for example, the conductive contacts 936 may include other analogous features (e.g., posts) that route the electrical signals to external components.

In some embodiments in which the integrated circuit device 900 is a double-sided die, the integrated circuit device 900 may include another metallization stack (not shown) on the opposite side of the device layer(s) 904. This metallization stack may include multiple interconnect layers as discussed above with reference to the interconnect layers 906-910, to provide conductive pathways (e.g., including conductive lines and vias) between the device layer(s) 904 and additional conductive contacts (not shown) on the opposite side of the integrated circuit device 900 from the conductive contacts 936.

In other embodiments in which the integrated circuit device 900 is a double-sided die, the integrated circuit device 900 may include one or more through silicon vias (TSVs) through the die substrate 902; these TSVs may make contact with the device layer(s) 904, and may provide conductive pathways between the device layer(s) 904 and additional conductive contacts (not shown) on the opposite side of the integrated circuit device 900 from the conductive contacts 936. In some embodiments, TSVs extending through the substrate can be used for routing power and ground signals from conductive contacts on the opposite side of the integrated circuit device 900 from the conductive contacts 936 to the transistors 940 and any other components integrated into the die 900, and the metallization stack 919 can be used to route I/O signals from the conductive contacts 936 to transistors 940 and any other components integrated into the die 900.

Multiple integrated circuit devices 900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 10 is a block diagram of an example electrical device 1000 that may include one or more of the embodiments disclosed herein. For example, any suitable ones of the components of the electrical device 1000 may include one or more of assemblies 100, integrated circuit devices 900, or integrated circuit dies 802 disclosed herein. A number of components are illustrated in FIG. 10 as included in the electrical device 1000, but any one or more of these components may be omitted or duplicated, as suitable for the application. In some embodiments, some or all of the components included in the electrical device 1000 may be attached to one or more motherboards mainboards, or system boards. In some embodiments, one or more of these components are fabricated onto a single system-on-a-chip (SoC) die.

Additionally, in various embodiments, the electrical device 1000 may not include one or more of the components illustrated in FIG. 10, but the electrical device 1000 may include interface circuitry for coupling to the one or more components. For example, the electrical device 1000 may not include a display device 1006, but may include display device interface circuitry (e.g., a connector and driver circuitry) to which a display device 1006 may be coupled. In another set of examples, the electrical device 1000 may not include an audio input device 1024 or an audio output device 1008, but may include audio input or output device interface circuitry (e.g., connectors and supporting circuitry) to which an audio input device 1024 or audio output device 1008 may be coupled.

The electrical device 1000 may include one or more processor units 1002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the processor unit 1002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1000 can comprise one or more processor units 1002 that are heterogeneous or asymmetric to another processor unit 1002 in the electrical device 1000. There can be a variety of differences between the processing units 1002 in a system in terms of a spectrum of metrics of merit including architectural, microarchitectural, thermal, power consumption characteristics, and the like. These differences can effectively manifest themselves as asymmetry and heterogeneity among the processor units 1002 in the electrical device 1000.

In some embodiments, the electrical device 1000 may include a communication component 1012 (e.g., one or more communication components). For example, the communication component 1012 can manage wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electrical device 1000 may include an antenna 1022 to facilitate wireless communications and/or to receive other wireless communications (such as AM or FM radio transmissions).

In some embodiments, the communication component 1012 may manage wired communications, such as electrical, optical, or any other suitable communication protocols (e.g., IEEE 802.3 Ethernet standards). As noted above, the communication component 1012 may include multiple communication components. For instance, a first communication component 1012 may be dedicated to shorter-range wireless communications such as Wi-Fi or Bluetooth, and a second communication component 1012 may be dedicated to longer-range wireless communications such as global positioning system (GPS), EDGE, GPRS, CDMA, WiMAX, LTE, EV-DO, or others. In some embodiments, a first communication component 1012 may be dedicated to wireless communications, and a second communication component 1012 may be dedicated to wired communications.

The electrical device 1000 may include battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any embedded or wired or wirelessly connected external device that generates an audible indicator, such speakers, headsets, or earbuds.

The electrical device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electrical device 1000 may include a Global Navigation Satellite System (GNSS) device 1018 (or corresponding interface circuitry, as discussed above), such as a Global Positioning System (GPS) device. The GNSS device 1018 may be in communication with a satellite-based system and may determine a geolocation of the electrical device 1000 based on information received from one or more GNSS satellites, as known in the art.

The electrical device 1000 may include another output device 1010 (or corresponding interface circuitry, as discussed above). Examples of the other output device 1010 may include an audio codec, a video codec, a printer, a wired or wireless transmitter for providing information to other devices, or an additional storage device.

The electrical device 1000 may include another input device 1020 (or corresponding interface circuitry, as discussed above). Examples of the other input device 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1000 may be any other electronic device that processes data. In some embodiments, the electrical device 1000 may comprise multiple discrete physical components. Given the range of devices that the electrical device 1000 can be manifested as in various embodiments, in some embodiments, the electrical device 1000 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example A1 is an integrated circuit package substrate comprising: a core layer comprising a spin-on-glass (SOG) material; a plurality of metal vias within the core layer, the metal vias electrically coupling a first side of the core layer and a second side of the core layer opposite the first side; and a plurality of build-up layers on the core layer, the build-up layers comprising metal vias electrically connected to the metal vias of the core layer.

Example A2 includes the subject matter of Example A1, wherein the core layer comprises an adhesion promotion layer between the SOG material and the metal vias.

Example A3 includes the subject matter of Example A2, wherein the adhesion promotion layer comprises Silicon and Oxygen or Silicon and Nitrogen.

Example A4 includes the subject matter of any one of Examples A1-A3, wherein sidewalls of the metal vias of the core layer are substantially perpendicular to the first side and second side of the core layer.

Example A5 includes the subject matter of any one of Examples A1-A4, wherein the SOG material is a first SOG material and the build-up layers comprise at least one layer comprising a second SOG material.

Example A6 includes the subject matter of Example A5, wherein the first SOG material and the second SOG material are different (e.g., concentrations of Boron or Phosphorus in the respective materials are substantially different).

Example A7 includes the subject matter of Example A5 or A6, wherein the plurality of build-up layers comprise a first build-up layer comprising a second SOG material and a second build-up layer comprising a third SOG material.

Example A8 includes the subject matter of Example A7, wherein the second SOG material and third SOG material are different (e.g., concentrations of Boron or Phosphorus in the respective materials are substantially different).

Example A9 includes the subject matter of any one of Examples A1-A8, comprising a device comprising circuitry within the SOG material of the core layer.

Example A10 is an integrated circuit package comprising the integrated circuit package substrate of any one of Examples A1-A9 and an integrated circuit die coupled to the package substrate.

Example A11 is a system comprising a main circuit board and the integrated circuit package of Example A10.

Example A12 is a method of forming a substrate core, comprising: forming a plurality of metal pillars on a carrier substrate; depositing a spin-on-glass (SOG) material adjacent the metal pillars; annealing the SOG material; removing the carrier substrate; and planarizing a top side and a bottom side of the stack comprising the SOG material and metal pillars to form substantially parallel planar surfaces, wherein each planar surface is defined at least in part by the SOG material and the metal pillars.

Example A13 includes the subject matter of Example AError! Reference source not found., further comprising conformally depositing an adhesion promotion material on the metal pillars before depositing the SOG material.

Example A14 includes the subject matter of Example A13, wherein the adhesion promotion material comprises Silicon and Oxygen or Silicon and Nitrogen.

Example A15 includes the subject matter of any one of Examples AError! Reference source not found.—A14, wherein depositing the SOG material comprises encapsulating the metal pillars with the SOG material.

Example A16 includes the subject matter of any one of Examples AError! Reference source not found.—A14, wherein at least a portion of the metal pillars are exposed after depositing the SOG material.

Example A17 includes the subject matter of any one of Examples AError! Reference source not found.—A16, wherein planarizing the top side or the bottom side of the stack comprises performing a chemical mechanical planarization (CMP) process.

Example A18 includes the subject matter of any one of Examples AError! Reference source not found.—A17, wherein the metal pillars are formed such that sidewalls of the pillars are substantially perpendicular with the carrier substrate.

Example A19 includes the subject matter of any one of Examples AError! Reference source not found.—A18, wherein the SOG material is a liquid having R-groups within a Silicon-Oxygen backbone dissolved in alcohol.

Example A20 includes the subject matter of any one of Examples AError! Reference source not found.—A19, further comprising embedding a device comprising circuitry in the SOG material before annealing the SOG material.

Example A21 includes the subject matter of any one of Examples AError! Reference source not found.—A20, wherein the further comprising forming a build-up layer on a planar surface of the stack, the build-up layer comprising metal pillars electrically connected to the metal pillars of the stack.

Example A22 includes the subject matter of Example A21, wherein the SOG material is a first SOG material, and forming the build-up layer comprises forming the metal pillars of the build-up layer and depositing a second SOG material adjacent the metal pillars of the build-up layer.

Example A23 includes the subject matter of Example A22, wherein the first SOG material and second SOG material are different (e.g., concentrations of Boron or Phosphorus in the respective materials are substantially different).

Example A24 is a product formed by the process of any one of Examples AError! Reference source not found.—A23.

Example B1 is an integrated circuit package substrate comprising: a core layer comprising a plurality of metal vias electrically coupling a first side of the core layer and a second side of the core layer opposite the first side; a build-up layer on the first side of the core layer, the build-up layer comprising metal vias within a spin-on-glass (SOG) material and electrically connected to the metal vias of the core layer.

Example B2 includes the subject matter of Example B1, wherein the build-up layer comprises an adhesion promotion layer between the SOG material and the metal vias.

Example B3 includes the subject matter of Example B2, wherein the adhesion promotion layer comprises Silicon and Oxygen or Silicon and Nitrogen.

Example B4 includes the subject matter of any one of Examples B1-B3, wherein the metal vias of the core layer are within silica.

Example B5 includes the subject matter of any one of Examples B1-B3, wherein the SOG material of the build-up layer is a first SOG material and the metal vias of the core layer are within a second SOG material.

Example B6 includes the subject matter of Example B5, wherein the first SOG material and the second SOG material are different (e.g., concentrations of Boron or Phosphorus in the respective materials are substantially different).

Example B7 includes the subject matter of any one of Examples B1-B6, wherein the build-up layer is a first build-up layer comprising a first SOG material, and the package substrate further comprises a second build-up layer on the first build-up layer, the second build-up layer comprising metal vias within a second SOG material and electrically connected to the metal vias of the first build-up layer.

Example B8 includes the subject matter of any one of Examples B1-B7, wherein the build-up layer is a first build-up layer comprising a first SOG material, and the package substrate further comprises a second build-up layer on the second side of the core layer, the second build-up layer comprising metal vias within a second SOG material and electrically connected to the metal vias of the core layer.

Example B9 is an integrated circuit package comprising an integrated circuit package substrate according to any one of Examples B1-B8 and an integrated circuit die coupled to the integrated circuit package substrate.

Example B10 is a system comprising a main circuit board and the integrated circuit package of Example B9.

Example B11 is a method of forming build-up layers of a substrate core, comprising: forming a plurality of first metal pillars; depositing a first spin-on-glass (SOG) material; annealing the first SOG material; planarizing a top surface of the first SOG material such that a portion of the first metal pillars are exposed on the top surface; forming a plurality of second metal pillars on the top surface of the SOG material, the second metal pillars in electrical connection with the first metal pillars; depositing a second SOG material; annealing the second SOG material; and planarizing a top surface of the second SOG material such that a portion of the second metal pillars are exposed on the top surface.

Example B12 includes the subject matter of Example B11, wherein the first metal pillars are formed on a carrier substrate, and the method further comprises: removing the carrier substrate; and coupling a substrate core layer comprising a plurality of third metal pillars to a bottom surface of the first SOG material such that the third metal pillars are in electrical connection with the first metal pillars.

Example B13 includes the subject matter of Example B11 or B12, wherein the first SOG material and second SOG material are different (e.g., concentrations of Boron or Phosphorus in the respective materials are substantially different).

Example B14 includes the subject matter of any one of Examples B11-B13, wherein the substrate core layer comprises a third SOG material.

Example B15 includes the subject matter of Example B14, wherein the third SOG material is different from the first SOG material and the second SOG material (e.g., concentrations of Boron or Phosphorus in the respective materials are substantially different).

Example B16 includes the subject matter of any one of Examples B11-B13, wherein the substrate core layer comprises silica.

Example B17 includes the subject matter of Example B11, wherein the first SOG material and second SOG material are liquids having R-groups within a Silicon-Oxygen backbone dissolved in alcohol.

Example B18 includes the subject matter of any one of Examples B11-B17, further comprising depositing an adhesion promotion material on the first metal pillars before depositing the first SOG material.

Example B19 includes the subject matter of Example B18, wherein the adhesion promotion material comprises Silicon and Oxygen or Silicon and Nitrogen.

Example B20 includes the subject matter of any one of Examples B11-B19, further comprising embedding a device comprising circuitry in the second SOG material before annealing the second SOG material.

Example B21 includes the subject matter of any one of Examples B11-B20, further comprising forming an organic build-up layer on the planarized top surface of the second SOG material.

Example B22 is a product formed by the process of any one of Examples B11-B21.

Example C1 is an integrated circuit package substrate comprising: a core layer comprising Silicon and Oxygen; a plurality of metal vias electrically coupling a first side of the core layer and a second side of the core layer opposite the first side; a build-up layer on the first side of the core layer, the build-up layer comprising metal pads and metal traces within a spin-on-glass (SOG) material, the metal pads and metal traces electrically connected to the metal vias of the core layer.

Example C2 includes the subject matter of Example C1, wherein the build-up layer comprises an adhesion promotion layer between the SOG material and the metal vias.

Example C3 includes the subject matter of Example C2, wherein the adhesion promotion layer comprises Silicon and Oxygen or Silicon and Nitrogen.

Example C4 includes the subject matter of any one of Examples C1-C3, wherein the core layer comprises silica.

Example C5 includes the subject matter of any one of Examples C1-C3, wherein the SOG material of the build-up layer is a first SOG material and the core layer comprises a second SOG material.

Example C6 includes the subject matter of Example C5, wherein the first SOG material and the second SOG material are different (e.g., concentrations of Boron or Phosphorus in the respective materials are substantially different).

Example C7 includes the subject matter of any one of Examples C1-C6, wherein the build-up layer is a first build-up layer comprising a first SOG material, and the package substrate further comprises a second build-up layer on the first build-up layer, the second build-up layer comprising metal vias within a second SOG material and electrically connected to the metal vias of the first build-up layer.

Example C8 includes the subject matter of Example C7, wherein the first SOG material and the second SOG material are different (e.g., concentrations of Boron or Phosphorus in the respective materials are substantially different).

Example C9 includes the subject matter of any one of Examples C1-C8, wherein the build-up layer is a first build-up layer comprising a first SOG material, and the package substrate further comprises a second build-up layer on the second side of the core layer, the second build-up layer comprising metal vias within a second SOG material and electrically connected to the metal vias of the core layer.

Example C10 includes the subject matter of Example C9, wherein the first SOG material and the second SOG material are different (e.g., concentrations of Boron or Phosphorus in the respective materials are substantially different).

Example C11 is an integrated circuit package comprising the integrated circuit package substrate of any one of Examples C1-C10 and an integrated circuit die coupled to the integrated circuit package substrate.

Example C12 is a system comprising a main circuit board and the integrated circuit package of Example C11.

Example C13 is a method of forming a build-up layer of a package substrate, comprising: depositing a photoresist material on a glass-based core layer comprising a plurality of metal vias; exposing a first portion of the photoresist material in a first pass; exposing a second portion of the photoresist material in a second pass; developing the first portion of the photoresist material to expose a first portion of the core layer; depositing a metal on the exposed first portion of the core layer; developing the second portion of the photoresist material to expose a second portion of the core layer; depositing a metal on the exposed second portion of the core layer; removing remaining photoresist material; depositing a spin-on-glass (SOG) material around the deposited metal; and annealing the SOG material.

Example C14 includes the subject matter of Example C13, further comprising planarizing a top surface of the stack comprising the core layer, the SOG material, and deposited metal, wherein at least a portion of the deposited metal is exposed after the planarizing.

Example C15 includes the subject matter of Example C14, wherein planarizing comprises performing a chemical mechanical planarization (CMP) process.

Example C16 includes the subject matter of any one of Examples C13-C15, wherein the glass-based core layer comprises silica.

Example C17 includes the subject matter of any one of Examples C13-C15, wherein the SOG material is a first SOG material, and the glass-based core layer comprises a second SOG material.

Example C18 includes the subject matter of Example C17, wherein the first SOG material and the second SOG material are different (e.g., concentrations of Boron or Phosphorus in the respective materials are substantially different).

Example C19 includes the subject matter of any one of Examples C13-C18, further comprising depositing an adhesion promotion material on the deposited metal before depositing the SOG material.

Example C20 includes the subject matter of Example C19, wherein the adhesion promotion material comprises Silicon and Oxygen or Silicon and Nitrogen.

Example C21 includes the subject matter of any one of Examples C13-C20, further comprising forming an organic build-up layer on the planarized top surface of the SOG material.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C). Additionally, it should be appreciated that items included in a list in the form of “at least one of A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature. Further, as used herein, the phrase “located on” in the context of a first layer or component located on a second layer or component may refer to the first layer or component being directly physically attached to the second part or component (no layers or components between the first and second layers or components) or physically attached to the second layer or component with one or more intervening layers or components. Additionally, as used herein, the term “adjacent” may refer to layers or components that are in physical contact with each other. That is, there is no layer or component between the stated adjacent layers or components. For example, a layer X that is adjacent to a layer Y refers to a layer that is in physical contact with layer Y.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An integrated circuit package substrate comprising:
a core layer comprising a plurality of metal vias electrically coupling a first side of the core layer and a second side of the core layer opposite the first side;
a build-up layer on the first side of the core layer, the build-up layer comprising metal vias within a dielectric material and electrically connected to the metal vias of the core layer, the dielectric material comprising Silicon, Oxygen, and at least one of Boron or Phosphorus.

2. The integrated circuit package substrate of claim 1, wherein the build-up layer comprises an adhesion promotion layer between the dielectric material and the metal vias.

3. The integrated circuit package substrate of claim 2, wherein the adhesion promotion layer comprises Silicon and Oxygen or Silicon and Nitrogen.

4. The integrated circuit package substrate of claim 1, wherein core layer further comprises silica.

5. The integrated circuit package substrate of claim 1, wherein the dielectric material of the build-up layer is a first dielectric material and the metal vias of the core layer are within a second dielectric material comprising Silicon, Oxygen, and at least one of Boron or Phosphorus.

6. The integrated circuit package substrate of claim 5, wherein a concentration of Boron or Phosphorus in the first dielectric material is substantially more than a concentration of Boron or Phosphorus in the second dielectric material.

7. The integrated circuit package substrate of claim 1, wherein the build-up layer is a first build-up layer comprising a first dielectric material, and the package substrate further comprises a second build-up layer on the first build-up layer, the second build-up layer comprising metal vias within a second dielectric material and electrically connected to the metal vias of the first build-up layer, the second dielectric material comprising Silicon, Oxygen, and at least one of Boron or Phosphorus.

8. The integrated circuit package substrate of claim 1, wherein the build-up layer is a first build-up layer comprising a first dielectric material, and the package substrate further comprises a second build-up layer on the second side of the core layer, the second build-up layer comprising metal vias within a second dielectric material and electrically connected to the metal vias of the core layer, the second dielectric material comprising Silicon, Oxygen, and at least one of Boron or Phosphorus.

9. An integrated circuit device comprising:
the integrated circuit package substrate, comprising:
a core layer comprising a plurality of metal vias electrically coupling a first side of the core layer and a second side of the core layer opposite the first side;
build-up layers on the core layer, the build-up layer comprising metal vias electrically connected to the metal vias of the core layer, at least one build-up layer comprising a dielectric material comprising Silicon, Oxygen, and at least one of Boron or Phosphorus; and
an integrated circuit die coupled to the integrated circuit package substrate.

10. The integrated circuit device of claim 9, wherein the build-up layer is a first build-up layer and the dielectric material is a first dielectric material, and the build-up layers further comprise a second build-up layer comprising a second dielectric material comprising Silicon, Oxygen, and at least one of Boron or Phosphorus.

11. The integrated circuit device of claim 9, wherein the dielectric material is a first dielectric material and the core layer comprises a second dielectric material comprising Silicon, Oxygen, and at least one of Boron or Phosphorus.

12. The integrated circuit device of claim 11, wherein a concentration of Boron or Phosphorus in the first dielectric material is substantially more than a concentration of Boron or Phosphorus in the second dielectric material.

13. The integrated circuit device of claim 9, wherein the core layer comprises silica.

14. A method of forming build-up layers of a substrate core, comprising:
forming a plurality of first metal pillars;
depositing a first dielectric material comprising Silicon, Oxygen, and at least one of Boron or Phosphorus;
annealing the first dielectric material;
planarizing a top surface of the first dielectric material such that a portion of the first metal pillars are exposed on the top surface;
forming a plurality of second metal pillars on the top surface of the dielectric material, the second metal pillars in electrical connection with the first metal pillars;
depositing a second dielectric material comprising Silicon, Oxygen, and at least one of Boron or Phosphorus;
annealing the second dielectric material; and
planarizing a top surface of the second dielectric material such that a portion of the second metal pillars are exposed on the top surface.

15. The method of claim 14, wherein the first metal pillars are formed on a carrier substrate, and the method further comprises:
removing the carrier substrate; and
coupling a substrate core layer comprising a plurality of third metal pillars to a bottom surface of the first dielectric material such that the third metal pillars are in electrical connection with the first metal pillars.

16. The method of claim 14, wherein a concentration of Boron or Phosphorus in the first dielectric material is substantially different from a concentration of Boron or Phosphorus in the second dielectric material.

17. The method of claim 14, wherein the substrate core layer comprises a third dielectric material comprising Silicon, Oxygen, and at least one of Boron or Phosphorus.

18. The method of claim 14, wherein the substrate core layer comprises silica.

19. The method of claim 14, wherein the first dielectric material and second dielectric material are liquids having R-groups within a Silicon-Oxygen backbone dissolved in alcohol.

20. The method of claim 14, further comprising depositing an adhesion promotion material on the deposited metal before depositing the dielectric material.
